(19) United States
(12) Patent Application Publication
(10) Pub. No.: US 2026/0112410 A1
(43) Pub. Date: Apr. 23, 2026

(54) Device and Method for Reducing Electromigration

(71) Applicant: Taiwan Semiconductor Manufacturing Company, Ltd., Hsinchu (TW)

(72) Inventors: Yumito Aoyagi, Hsinchu (TW); Makoto Yabuuchi, Hsinchu (TW)

(21) Appl. No.: 18/921,123

(22) Filed: Oct. 21, 2024

(51) Int. Cl. G11C 11/419; G11C 11/412

(52) U.S. Cl. CPC G11C 11/419; G11C 11/412

(57) ABSTRACT

A memory device includes a memory array, a plurality of sense amplifiers, a plurality of tracking circuits, and a tracking circuit activator. The memory array includes a plurality of bit cells that store data therein, a plurality of word lines each connected to the bit cells in a respective row, and a plurality of bit line pairs each connected to the bit cells in a respective column. Each sense amplifier amplifies a voltage difference between a respective bit line pair in response to a sense amplifier enable signal. The voltage difference represents a bit stored in a bit cell. The tracking circuits are connected to each of the sense amplifiers. Each tracking circuit mimics a behavior of the memory array and generates the sense amplifier enable signal when activated. The tracking circuit activator activates the tracking circuits according to a predefined activation protocol.

### BACKGROUND

Memory devices, such as static random access memory (SRAM) devices, store data through write operations and allows retrieval of the data through subsequent read operations. The memory device includes a plurality of bit cells arranged in an array of rows and columns. Each bit cell stores a bit, e.g., logic 0 or 1, of data therein. Control circuitry manages memory operations, including write and read operations. It is desirable for the control circuitry to ensure precise timing, efficient operation, and reliable performance of the memory device.

### BRIEF DESCRIPTION OF THE DRAWINGS

Aspects of the present disclosure are best understood from the following detailed description when read with the accompanying figures:

FIG. 1 is a schematic block diagram illustrating an exemplary memory device in accordance with various embodiments of the present disclosure;

FIG. 2 is a schematic circuit diagram illustrating an exemplary memory array in accordance with various embodiments of the present disclosure;

FIG. 3 is a schematic block/circuit diagram illustrating an exemplary sense amplifier connected between a bit cell and a tracking circuit in accordance with various embodiments of the present disclosure;

FIG. 4 is a schematic block/circuit diagram illustrating a tracking circuit connected to peripheral circuits in accordance with various embodiments of the present disclosure;

FIG. 5 is a schematic block diagram illustrating another exemplary memory device in accordance with various embodiments of the present disclosure;

FIGS. 6A-6D are schematic block diagrams illustrating exemplary activations of tracking circuits in accordance with various embodiments of the present disclosure;

FIG. 7 is a schematic circuit diagram illustrating an exemplary multiplexer in accordance with various embodiments of the present disclosure;

FIG. 8 is a schematic circuit diagram illustrating another exemplary multiplexer in accordance with various embodiments of the present disclosure;

FIG. 9 is a schematic circuit diagram illustrating an exemplary tracking circuit activator in accordance with various embodiments of the present disclosure;

FIG. 10 is a schematic circuit diagram illustrating another exemplary tracking circuit activator in accordance with various embodiments of the present disclosure;

FIG. 11 is a schematic block diagram illustrating another exemplary memory device in accordance with various embodiments of the present disclosure; and

FIG. 12 is a flowchart of an exemplary method for reducing electromigration in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underneath,” “below,” “lower,” “above,” “on,” “top,” “bottom” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

Control circuitry manages memory operations of a memory device, including write and read operations. Memory devices, such as static random access memory (SRAM) devices, store data through write operations and allow retrieval of the data through subsequent read operations. It is desirable for the control circuitry to ensure precise timing, efficient operation, and reliable performance of the memory device. This is achieved with the use of a tracking circuit that mimics the behavior of the memory device, e.g., during write or read operations. For example, the tracking circuit keeps tracks of the various stages of a write or read operation from initiation to completion. Once a write or read operation is done, the tracking circuit generates a signal or flag indicating the end of the operation. This signal can be used by the control circuitry to proceed with subsequent operations.

In some operating environments, the tracking circuit is activated frequently over a short period of time, which may result in electromigration in the tracking circuit. Electromigration is a phenomenon where a gradual movement of metal atoms in a conductor occurs due to the momentum transfer from the electrons flowing through the material, which can lead to eventual degradation or failure of the conductor. System and methods as described herein may, in certain embodiments, provide two or more tracking circuits. By alternating or otherwise dividing the activation of these tracking circuits across stages of a write or read operation, this process can reduce, if not eliminate, the degradation of the tracking circuits due to electromigration.

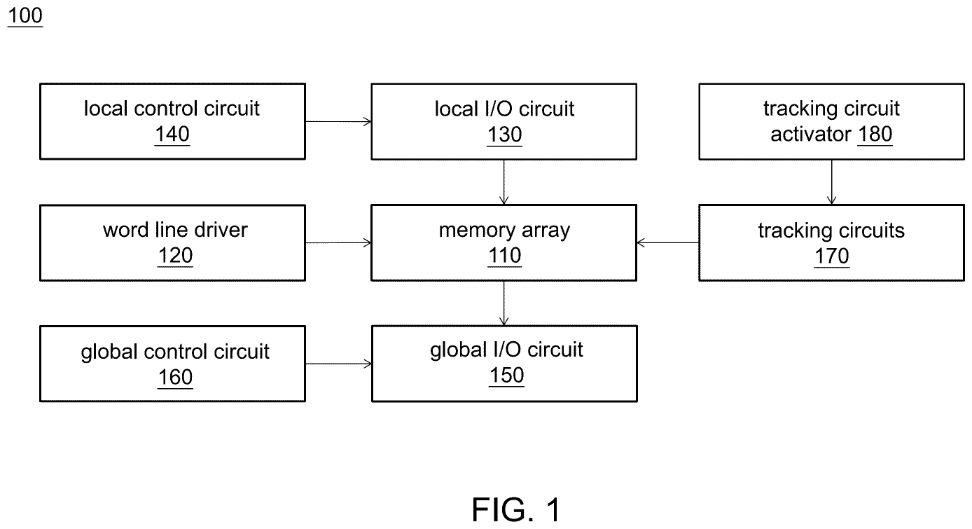

FIG. 1 is a schematic block diagram illustrating an exemplary memory device 100 in accordance with various embodiments of the present disclosure. In certain embodiments, the memory device 100 is, e.g., a random access memory (RAM) device, such as a static random access memory (SRAM) device. As illustrated in FIG. 1, the example memory device 100 includes one or more memory arrays 110 and a number of peripheral circuits, such as a word line driver 120, a local input/output (IO) circuit 130, a local control circuit 140, a global I/O circuit 150, a global control circuit 160, a plurality of tracking circuits 170, and a tracking circuit activator 180. The memory device 100 may include other components not shown in FIG. 1. In this exemplary embodiment, the memory device 100 can be part of a semiconductor chip (a.k.a., integrated circuit or a semiconductor die).

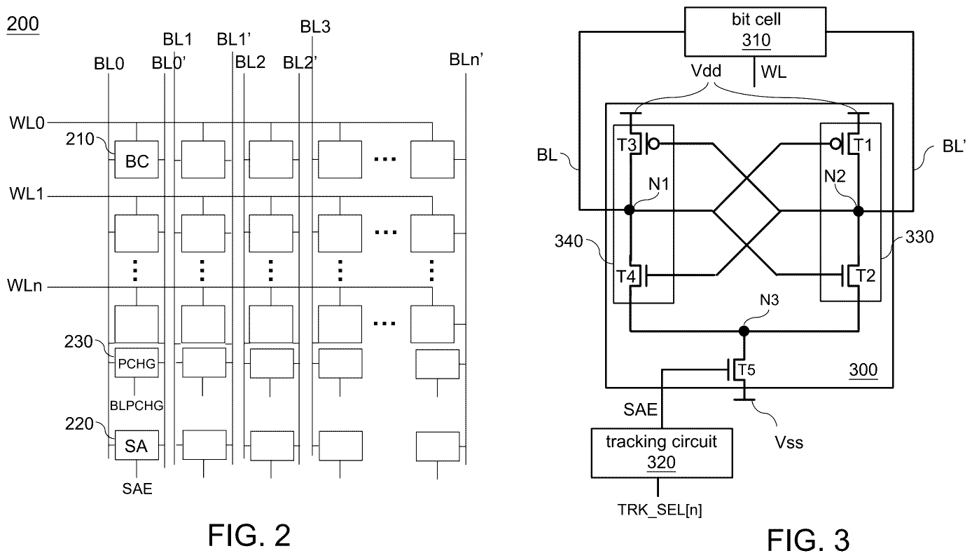

The memory array 110 stores data through write operations, allows retrieval of the data stored therein through subsequent read operations, and includes a plurality of bit cells, e.g., bit cells 210 of FIG. 2. Each bit cell 210 stores one bit of information in the form of ‘0’ or ‘1’. In some embodiments, the bit cell 210 is a 6T bit cell and includes six transistors (e.g., two cross-coupled inverters forming a latch and two access transistors). In other embodiments, the bit cell 210 is an 8T bit cell, a 4T bit cell (including four transistors and two resistors), a 10T bit cell, a dual-port bit cell, and a 1T1C bit cell (including one transistor and a capacitor). The peripheral devices 120-180 provide various functions of the memory device 100 associated with the memory array 110. For example, the word line driver 120 selects a word line, e.g., word lines (WL0-WLn) of FIG. 2, and drives the selected word line to a logic high. The logic high is substantially equal to a supply voltage (Vdd). In certain embodiments, the word line driver 120 comprises a decoder that includes a plurality of logic operators to decode voltages on address lines to identify a word line to activate. The address lines are charged to logic high or logic low (i.e., a reference voltage Vss or ground).

The local I/O circuit 130 writes and reads data to and from the memory array 110. For example, the local I/O circuit 130 senses voltage levels at the plurality of bit line pairs, e.g., bit line pair (BL0-BLn, BL0-BLn′) of FIG. 2, and compares the voltage levels for each pair. For example, when the voltage level of a first bit line is more than the voltage level a second bit line of a bit line pair, the local I/O circuit 130 reads the output to be logic 1. Conversely, when the voltage levels of the first bit line is less than the voltage level of the second bit line, the local I/O circuit 230 reads the output to be logic 0. The local control circuit 140 controls operation of the local I/O circuit 130. For example, the local control circuit 140 configures the local I/O circuit 130 in a write mode to store information in the memory array 110 or a read mode to retrieve information from the memory array 110. In addition, the local control circuit 140 enables the local I/O circuit 130 in a hold mode where no data is written to or read from the memory array 110. The global I/O circuit 150 combines the input/output from the local I/O circuit 130. For example, the memory arrays 110 each having a respective local I/O circuit 130. The global I/O circuit 150 combines the information from the local IO circuits 130 into the global I/O circuit. Each local I/O circuit 130 then stores the output from the memory arrays 110, e.g., in a shift register. The global I/O circuit 150 reads the data from the shift register and provides the data as an output of memory device 100.

The global control circuit 160 controls operation of the global I/O circuit 150. For example, the global control circuit 160 enables the global I/O circuit 150 to select one or more local I/O circuits 130 to read data from or write data to the memory arrays 110. As another example, the global control circuit 160 enables a reading sequence for the global I/O circuit 150 to read data from or a writing sequence to write data into one or more local I/O circuits 130. As will be described in detail further below, the tracking circuit activator 180 activates the tracking circuits 170 according to a predefined activation protocol. For example, this predefined activation protocol includes activating the tracking circuits 170 sequentially, cyclically, randomly, pseudorandomly, alternately, in a clockwise pattern, in a counter-clockwise pattern, in an interlace manner, in a zigzag pattern (e.g., activating the tracking circuits in the first row or column first, followed by the tracking circuits in the second row or column), or combinations thereof.

FIG. 2 is a schematic block diagram illustrating an exemplary memory array 200, e.g., memory array 110, in accordance with various embodiments of the present disclosure. As illustrated in FIG. 2, the example memory array 200 includes a plurality of bit cells 210 arranged in an array of rows and columns. For clarity, only one of the bit cells 210 is labeled in FIG. 2. The bit cells 210 in each row are connected to a word line (WL0-WLn). Similarly, the memory cells 210 in each column are connected between the bit line pair (BL0-BLn, BL0′-BLn′). The bit cell 210 stores a bit of data therein, representing a logic 0 or 1. The memory array 200 further includes a plurality of the sense amplifiers (only one of the sense amplifiers is labeled as 220 in FIG. 2), each connected between the bit line pair (BL0-BLn, BL0′-BLn′). The sense amplifier 220 receives a sense amplifier enable signal (SAE) and detects and amplifies a voltage difference between the bit line pair (BL0-BLn, BL0′-BLn′) in response to the sense amplifier 220 enable signal (SAE). The local I/O circuit 130 then determines whether the bit stored in the bit cell 210 is ‘0’ or ‘1’. For example, if the voltage level on the bit line (BL0-BLn) is greater than the voltage level on the bit line (BL0′-BLn′), the sense amplifier 220 generates a logic high or ‘1’ output. Otherwise, it generates logic low or ‘0’ output. The global I/O circuit 150 then outputs the bit stored in the bit cell as either ‘0’ or ‘1’.

The memory array 110 further includes a plurality of pre-chargers (only one of the sense pre-charges is labeled as 230 in FIG. 2), each connected between the bit line pair (BL0-BLn, BL0′-BLn′). The pre-charger 230 receives a bit line pre-charge signal (BLPCHG) and, in response to the bit line pre-charge signal (BLPCHG), pre-charges the bit line pair (BL0-BLn, BL0′-BLn′) to a predetermined voltage level. This level can be substantially equal to the supply voltage (Vdd), the reference voltage (Vss) or ground, or halfway between the supply and reference voltages (Vdd, Vss), thereby equalizing the voltage levels on the bit line pair (BL0-BLn, BL0′-BLn′). This ensures that the voltage difference detected by the sense amplifier 220 is solely due to the data stored in the bit cell 210.

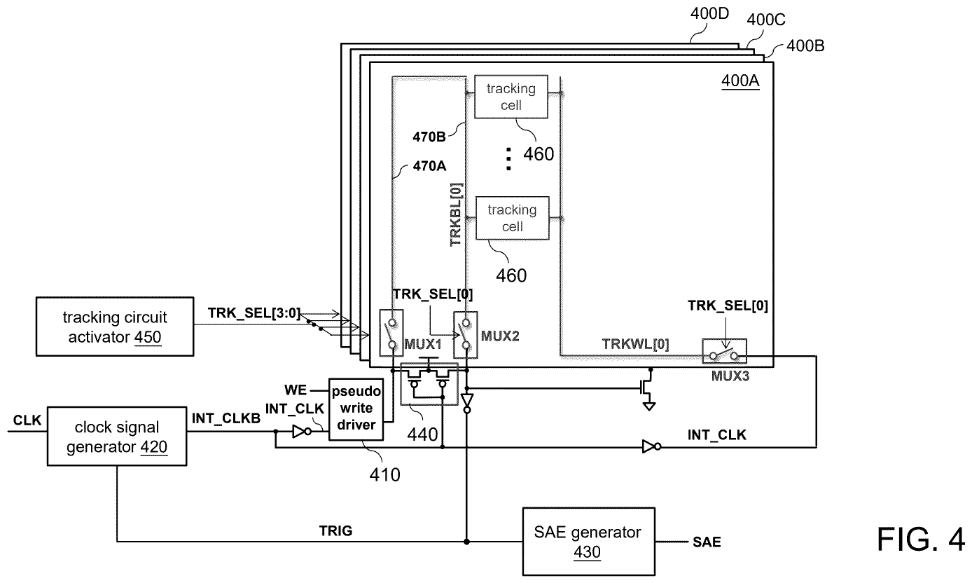

FIG. 3 is a schematic block/circuit diagram illustrating an exemplary sense amplifier 300, e.g., sense amplifier 220, connected between a bit cell 310, e.g., bit cell 210 of FIG. 2, and a tracking circuit 320, e.g., tracking circuit 400A-400D of FIG. 4, in accordance with various embodiments of the present disclosure. As illustrated in FIG. 3, the example sense amplifier 300 is connected across the supply voltage (Vdd) node and the reference voltage (Vss) (or ground) node and includes first-third sense amplifier nodes (N1-N3), first and second cross-coupled inverters 330, 340, and a transistor (T5). The sense amplifier 300 node (N1) serves as both the input of the inverter 330 and the output of the inverter 340 and is connected to the bit line (BL). The sense amplifier 300 node (N2) serves as both the input of the inverter 340 and the output of the inverter 330 and is connected to the complementary bit line (BL′). The inverter 330, 340 is connected between the supply voltage (Vdd) node and the sense amplifier 300 node (N3) and includes first and second transistors (T1, T3, T2, T4).

The transistor (T5) has a first source/drain terminal connected to the sense amplifier 300 node (N3), a second source/drain terminal connected to the reference voltage (Vss) (or ground) node, and a gate terminal that receives a sense amplifier 300 enable signal (SAE). In an exemplary read operation, the bit line pair (BL, BL′) are initially pre-charged to a predetermined voltage level, e.g., substantially equal to the supply voltage (Vdd), the reference voltage (Vss), or halfway between the supply and references voltages (Vdd, Vss). When the sense amplifier 300 enable signal (SAE) is asserted, the transistor (T5) turns on, activating the sense amplifier 300. At this time, one of the inverters 330, 340 amplifies the voltage level on one of the bit lines, e.g., bit line (BL), driving its output to a logic state, e.g., 1. At substantially the same time, the input of the other of the inverters 330, 340 is pulled toward the opposite logic state, e.g., 0, thereby stabilizing the logic state at the bit line (BL). This process permits a memory controller to accurately read a bit stored in the bit cell 310. Thereafter, the sense amplifier 300 is deactivated by the sense amplifier 300 enable signal (SAE) and the bit line pair (BL, BL′) are pre-charged again in preparation for the next read operation.

The tracking circuit 320 is connected to the gate terminal of the transistor (T5) of the sense amplifier 220 and receives a tracking select signal (TRK_SEL[n]). In response to the tracking select signal (TRK_SEL[n]), the tracking circuit 320 facilitates generation of a sense amplifier 300 enable signal (SAE). In this exemplary embodiment, the tracking circuit 320 mimics the behavior of the memory device 100 by accounting for delays experienced by signals traveling along the actual bit line (BL, BL′) and/or word line (WL) during read and write operations, caused by factors such as capacitance, resistance, and the inherent speed of the bit cell 310. The tracking circuit 320 keeps tracks of the various stages of a write or read operation from initiation to completion. Once the write or read operation is done, the tracking circuit 320 generates a signal or flag indicating the end of the operation, which can be used by control circuitry to proceed with subsequent memory operations.

FIG. 4 is a schematic block/circuit diagram illustrating exemplary tracking circuits 400A-400D, e.g., tracking circuit 320, connected to peripheral circuits 410-450 in accordance with various embodiments of the present disclosure. Because the tracking circuits 400A-400D are similar in structure and operation, only the tracking circuit 400A will be described hereinbelow. As illustrated in FIG. 4, the example tracking circuit 400A includes a tracking bit line (TRKBL[0]), a tracking word line (TRKWL[0]), a plurality of tracking bit cells 460, and plurality of multiplexers (MUX1-MUX3). The tracking bit line (TRKBL[0]) emulates or reflects the delays encountered by the bit line pair (BL, BL′) during read and write operations. In this exemplary embodiment, the tracking bit line (TRKBL[0]) is in a winding or serpentine pattern. This increases its length without extending its lengthwise footprint. The tracking word line (TRKWL[0]) emulates or duplicates the delays experienced by signals traveling along the actual word line (WL) during read and write operations, caused by factors such as capacitance and resistance of the actual word line (WL). The tracking bit cells 460 are connected between the tracking bit line (TRKBL[0]) and the tracking word line (TRKWL[0]) and emulates or replicates the timing of the bit cell 310 as it stores and outputs a bit.

The memory device 100 further includes a pseudo write driver 410, a clock signal generator 420, a sense amplifier enable signal (SAE) generator 430, a pre-charger 440, and a tracking circuit activator 450. The pseudo write driver 410 mimics or replicates the behavior of an actual write driver during a write operation on the memory device 100, e.g., matching the delay experienced by the actual write driver. For example, the pseudo write driver 410 receives a write enable signal (WE) (e.g., from the global control circuit 160) and an internal clock signal (INT_CLK) and applies a voltage level sufficient to activate the tracking bit cell 460. The clock signal generator 420 receives a clock signal (CLK) (e.g., from a clock source external to the memory device 100) and generates an inverted version of the internal clock (INT_CLK) that corresponds to the clock signal (CLK) and that drives the tracking word line (TRKWL[0]).

The sense amplifier enable signal (SAE) generator 430 receives a combination of a voltage level applied to the tracking bit line (TRKBL[0]) by the pseudo write driver 410 and a trigger signal (TRIG) generated by the clock signal generator 420 based on the clock signal (CLK) to generate a sense amplifier enable signal (SAE). The pre-charger 440 is connected between segments 470A, 470B of the tracking bit line (TRKBL) and pre-charges them to a predetermined voltage level, e.g., substantially equal to the supply voltage (Vdd), the reference voltage (Vss), or halfway between the supply and references voltages (Vdd, Vss), in response to the inverted version of the internal clock signal (INT_CLK).

The tracking circuit 400A further includes first-third multiplexers (MUX1-MUX3). The multiplexer (MUX1) is connected between the output terminal of the pseudo write driver 410 and the segment 470A of the tracking bit line (TRKBL[0]), receives a tracking select signal (TRK_SEL[0]), and selectively connects the output terminal of the pseudo write driver 410 to the segment 470A of the tracking bit line (TRKBL[0]) in response to the tracking select signal (TRK_SEL[0]). Similarly, the multiplexer (MUX2) is connected between the segment 470B of the tracking bit line (TRKBL[0]) and the input terminal of the sense amplifier enable signal (SAE) generator 430, receives the tracking select signal (TRK_SEL[0]), and selectively connects the segment 470B of the tracking bit line (TRKBL[0]) to the input terminal of the sense amplifier enable signal (SAE) generator 430 in response to the tracking select signal (TRK_SEL[0]). Additionally, the multiplexer (MUX3) is connected between the output terminal of the clock signal generator 420 and the tracking word line (TRKWL[0]), receives the tracking select signal (TRK_SEL[0]), and selectively connects the output terminal of the clock signal generator 420 to the tracking word line (TRKWL[0]) in response to the tracking select signal (TRK_SEL[0]). The tracking circuit activator 450 generates the tracking select signals (TRK_SEL[3:0]) according to a predefined activation protocol that distributes workload across the tracking circuits 400A-400D, whereby the degradation of a tracking circuit due to electromigration can be reduced or eliminated. For example, this predefined activation protocol includes activating the tracking circuits 400A-400D sequentially, cyclically, in a clockwise or counter-clockwise manner, in an interlace manner, in a zigzag manner (e.g., activating the tracking circuits in the first row or column first, followed by the tracking circuits in the second row or column), randomly, pseudorandomly, alternately, or combinations thereof.

In an exemplary read operation, the pre-charger 440 initially pre-charges the segments 470A, 470B of the tracking bit line (TRKBL[0]) to a predetermined voltage level. The tracking circuit 400A is then activated by asserting the tracking select signal (TRK_SEL[0]) on the multiplexers (MUX1-MUX3). Next, the clock signal generator 420 generates an inverted version of the internal clock signal (INT_CLK) that corresponds to the clock signal (CLK). This permits the pseudo write driver 410 to apply a voltage level to the tracking bit line (TRKBL[0]). At substantially the same time, the inverted version of the internal clock signal (INT_CLK) drives the tracking word line (TRKWL[0]), whereby the tracking bit cell 460 mirrors the writing or reading operation of an actual bit cell. e.g., bit cell 210. Subsequent to the clock generator 420 generating the trigger signal (TRIG) based on the clock signal (CLK), the sense amplifier enable signal (SAE) generator 430 asserts a sense amplifier enable signal (SAE) on a sense amplifier, e.g., sense amplifier 300, thereby activating the sense amplifier.

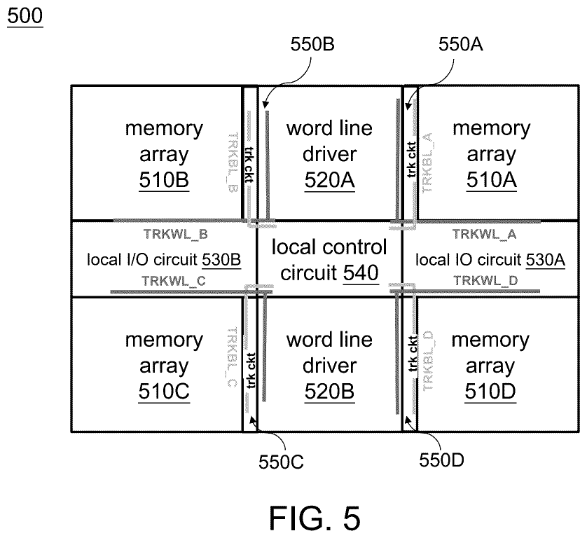

FIG. 5 is a schematic block diagram illustrating another exemplary memory device 500, e.g., memory device 100, in accordance with various embodiments of the present disclosure. As illustrated in FIG. 5, the example memory device 500 includes first-fourth memory arrays 510A-510D, first and second word line drivers 520A, 520B, a local I/O circuit 530A, 530B, and first-fourth tracking circuits 550A-550D. Each memory array 510A-510D, e.g., memory array 200, is disposed at a respective corner of the memory device 500. The word line driver 520A, 520B, e.g., word line driver 120, is disposed between the memory arrays 510A, 510B, 510C, 510D. The local I/O circuit 530A, 530B, e.g., local I/O circuit 130, is disposed between the memory arrays 510A, 510D, 510B, 510C. The local control circuit 540, e.g., local control circuit 140, is surrounded by the memory arrays 510A, 510B, 510C, 510D, the word line drivers 520A, 520B, and the local I/O circuits 530A, 530B. The tracking circuit 550A-550D, e.g., tracking circuits 400A-400D, is adjacent the memory array 510A-510D.

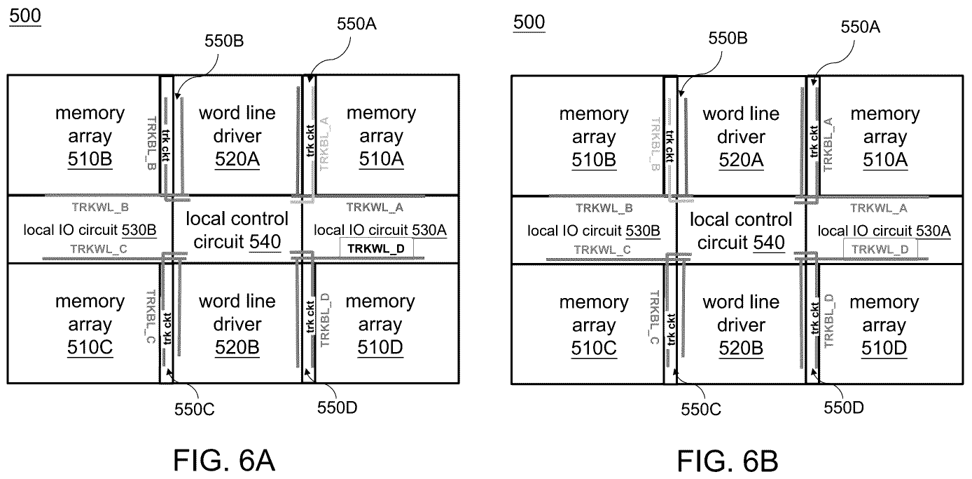

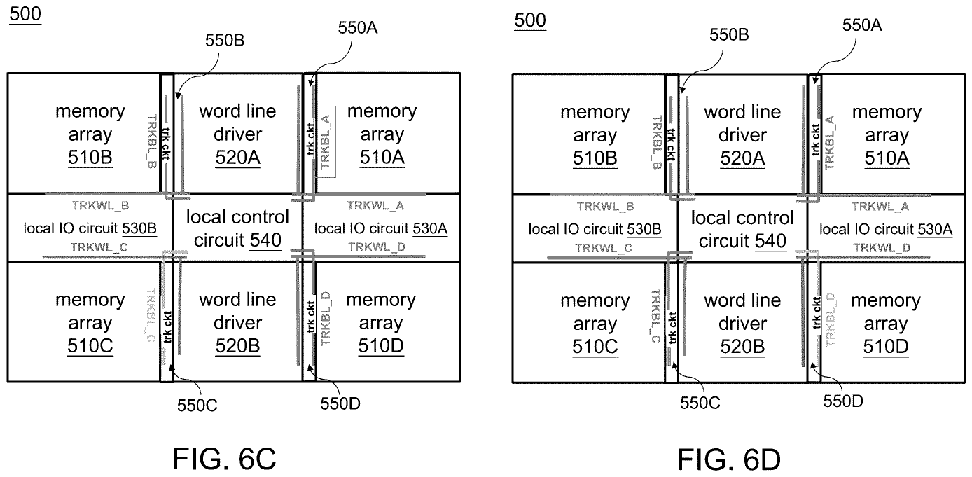

The construction as such of the memory device 500 enables memory operations, such as writing to or reading from the memory array 510-540, by activating the tracking circuits 550A-550D according to a predefined activation protocol (e.g., activating the tracking circuits 550A-550D sequentially, cyclically, randomly, pseudorandomly, alternately, in a clockwise pattern, in a counter-clockwise pattern, in a zigzag pattern, in an interlace manner, or combinations thereof). Such activation mitigates the risk of electromigration in the tracking circuits 550A-550D, thereby facilitating precise timing, efficient operation, and reliable performance of the memory device 500 of the present disclosure. For example, FIGS. 6A-6D are schematic block diagrams illustrating an exemplary activation of the tracking circuits 550A-550D of the memory device 500 in accordance with various embodiments of the present disclosure.

As illustrated in FIG. 6A, when a memory operation (e.g., a write or read operation) is performed on a first bit cell of the memory arrays 510A-510D, the tracking circuit 550A is activated to track, e.g., the completion of, the memory operation on the first bit cell. In the subsequent write or read operation on a second bit cell, as illustrated in FIG. 6B, the tracking circuit 550B is activated to track, e.g., the completion of, the memory operation on the second bit cell. Following this, as illustrated in FIG. 6C, the tracking circuit 550C is activated to track, e.g., the completion of, the memory operation on a third bit cell. Before the cycle repeats with the activation of the tracking circuit 550A, the tracking circuit 550D is activated to track, e.g., the completion of, the memory operation on a fourth bit cell, as shown in FIG. 6D. This round-robin activation of the tracking circuits 550A-550D facilitates evenly distributes the write and read operations across the tracking circuits 550A-550D, preventing occurrence of electromigration that can result if the same tracking circuit is activated for every write or read operation. In this exemplary embodiment, each tracking circuit 550A-550D is activated once in each sequence. In an alternative embodiment, each tracking circuit 550A-550D is activated more than once, e.g., twice, in each sequence.

Although the memory device 500 is exemplified with the tracking circuits 550A-550D activated in a counter-clockwise sequence, it should be understood that, after reading this disclosure, the tracking circuits 550A-550D can be activated in any order. This includes sequentially, cyclically, alternately, in a clockwise manner, in a zigzag manner, randomly, pseudorandomly, or combinations thereof.

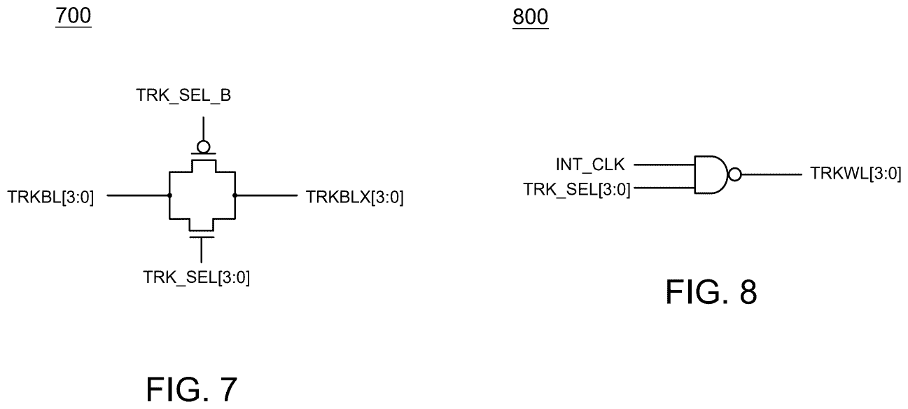

FIG. 7 is a schematic circuit diagram illustrating an exemplary multiplexer, e.g., multiplexer (MUX1, MUX2), in accordance with various embodiments of the present disclosure. As illustrated in FIG. 7, the example multiplexer (MUX1, MUX2) includes a transmission gate 700. A transmission gate permits analog or digital signals to pass therethrough bidirectionally. It includes a pair complementary MOSFETs (Metal-Oxide-Semiconductor Field-Effect Transistors), one N-channel (NMOS) and one P-channel (PMOS), connected in parallel. For example, the transmission gate 700 has a first control terminal that receives the tracking select signal (TRK_SEL[3:0]), a second control terminal that receives an inverted version of the tracking select signal (TRK_SEL[3:0]), an input terminal connected to the tracking bit line (TRKBL[3:0]), and an output terminal connected to the pseudo write driver 410 (or the clock signal generator 420).

In an exemplary write or read operation, with further reference to FIG. 4, when the tracking select signal (TRK_SEL[3:0]) is logic high (i.e., the inverted version of the tracking select signal TRK_SEL[3:0] is logic low), both the NMOS and PMOS transistors conduct. This allows the pseudo write driver 410 to drive the tracking bit line (TRKBL[3:0]). Otherwise, when the tracking select signal (TRK_SEL[3:0]) is logic low (i.e., the inverted version of the tracking select signal TRK_SEL[3:0] is logic high, both the NMOS and PMOS transistors turned off). As a result, the pseudo write driver 410 is blocked from driving the tracking bit line (TRKBL[3:0]). Other circuits for the multiplexer (MUX1, MUX2) are contemplated in an alternative embodiment.

FIG. 8 is a schematic circuit diagram illustrating an exemplary multiplexer, e.g., multiplexer (MUX3), in accordance with various embodiments of the present disclosure. As illustrated in FIG. 8, the example multiplexer (MUX3) includes a NAND gate 800. A NAND gate is a digital logic gate that outputs a logic 0 when all its inputs are logic 1. Otherwise, it outputs a logic 1. For example, the NAND gate 800 has a first input terminal that is connected to the output terminal of the clock generator and that receives the internal clock signal (INT_CLK), a second input terminal that receives the tracking select signal (TRK_SEL[3:0]), and an output terminal that is connected to the tracking word line (TRKWL[3:0]) and that drives the tracking word line (TRKWL[3:0]) with the internal clock signal (INT_CLK).

In an exemplary write or read operation, with further reference to FIG. 4, when the tracking select signal (TRK_SEL[3:0]) is logic high, the clock signal generator 420 drives the tracking word line (TRKWL[3:0]). Otherwise, when the tracking select signal (TRK_SEL[3:0]) is logic low, the clock signal generator 420 is blocked from driving the tracking word line (TRKWL[3:0]). Other circuits for the multiplexer (MUX3) are contemplated in an alternative embodiment.

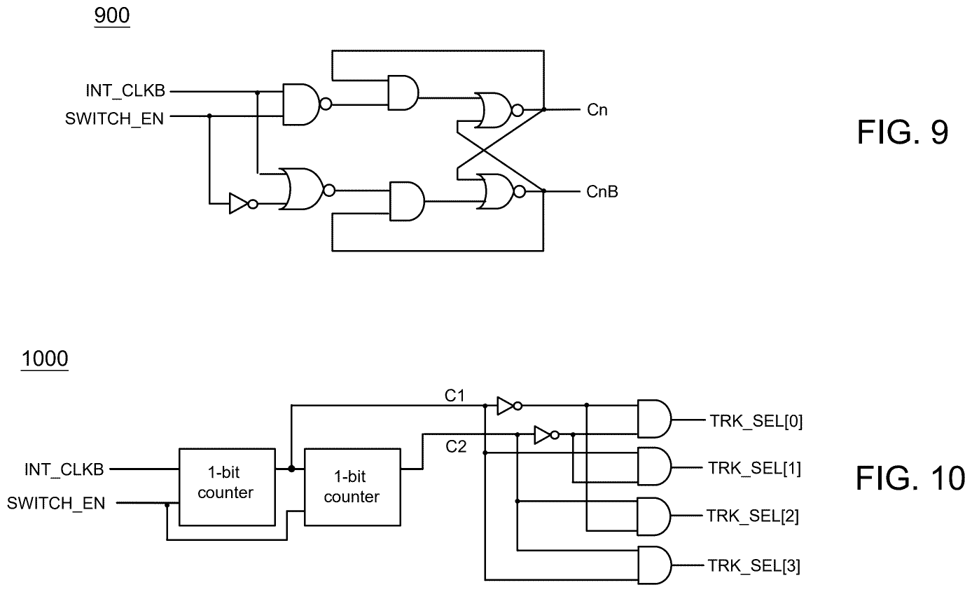

FIG. 9 is a schematic circuit diagram illustrating an exemplary tracking circuit activator, e.g., tracking circuit activator 450, in accordance with various embodiments of the present disclosure. As illustrated in FIG. 9, the example tracking circuit activator 450 is in the form of a counter 900. It receives an inverted version of the internal clock signal (INT_CLKB) and an enable signal (SWITCH_EN) to generate complementary outputs (Cn, CnB). These complementary outputs (Cn, CnB) can be in four possible states: (i) Cn=0, CnB=0; (ii) Cn=0, CnB=1; (iii) Cn=1, CnB=0, and (iv) Cn=1, CnB=1. In certain embodiments, the complementary outputs (Cn, CnB) are used to generate tracking select signals (TRK_SEL[3:0]). These signals cycle through 0001, 0010, 0100, 1000, and then back to 0001, in conjunction with other one or more components.

FIG. 10 is a schematic a schematic circuit diagram illustrating an exemplary tracking circuit activator, e.g., tracking circuit activator 450, in accordance with various embodiments of the present disclosure. As illustrated in FIG. 10, the example tracking circuit activator 450 is in the form of a counter 1000 that receives an inverted version of the internal clock signal (INT_CLKB) and an enable signal (SWITCH_EN) to generate complementary outputs (C1, C2). These complementary outputs (Cn, CnB) can be in four possible states: (i) C1=0, C2=0; (ii) C1=0, C2=1; (iii) C1=1, C2=0, and (iv) C1=1, C2=1. In certain embodiments, the complementary outputs (C1, C2) can be used to generate, e.g., tracking select signals (TRK_SEL[3:0]). These signals cycle through 0001, 0010, 0100, 1000, and then back to 0001 in conjunction with other components, e.g., logic gates, such as inverters and AND gates, as shown in FIG. 10.

In certain embodiments, the tracking select signal (TRK_SEL[3:0]) is generated based on a column address. A column address selects a specific column within a memory array where the desired bit cell is located. In some embodiments, the tracking select signal (TRK_SEL[3:0]) is generated based on a bank address. A bank address selects a specific memory bank within a memory device. A memory device includes a plurality of memory banks, each including one or more memory arrays. This allows for efficient parallel access and improved performance by distributing the memory operations across different banks. In other embodiments, the tracking select signal (TRK_SEL[3:0]) is generated by a phase selector. A phase selector is responsible for adjusting and selecting the phase of clock signals to ensure proper timing alignment for memory operations.

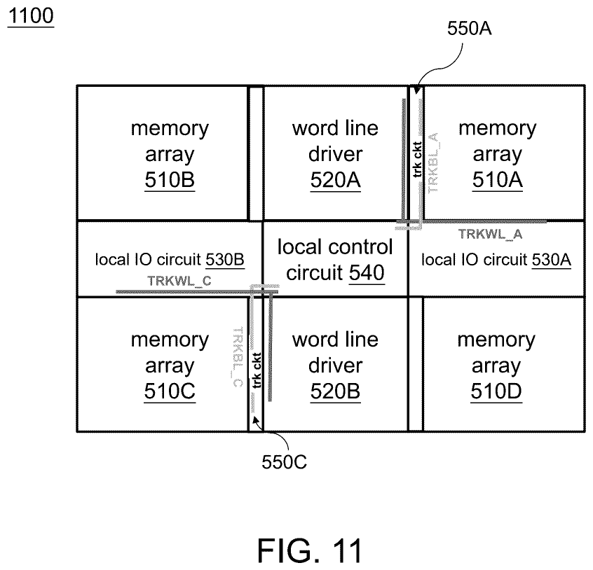

Although the memory device 500 is exemplified with four memory arrays 510A-510D and four tracking circuits 550A-550D, it should be understood that, after reading this disclosure, the number of memory arrays/tracking circuits may be increased or decreased as desired and the number of tracking circuits may not be necessarily equal to the number of memory arrays, provided the number of tracking circuits is more than one. For example, FIG. 11 is a schematic block diagram illustrating another exemplary memory device 1100 in accordance with various embodiments of the present disclosure. As illustrated in FIG. 11, the example memory device 1100 differs from the memory device 500 in that the memory device 1100 is dispensed with the tracking circuits 550B, 550D. In this exemplary embodiment, the memory device 1100 allows for writing to or reading from bit cells of the memory array 510-540 by sequentially activating the tracking circuits (580A, 580C). In an alternative embodiment, the number of tracking circuits is greater than the number of memory arrays.

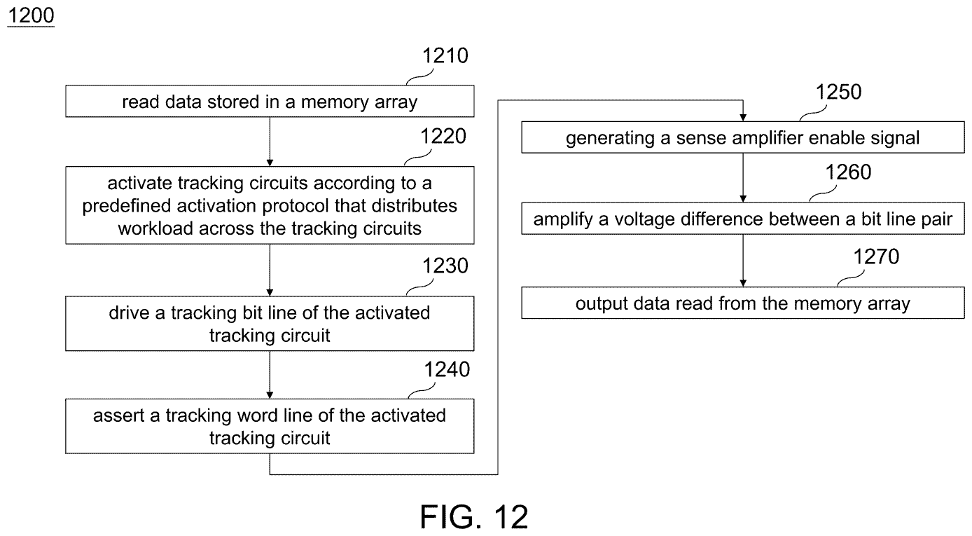

FIG. 12 is a flowchart of an exemplary method 1200 for reducing electromigration in a memory device, e.g., memory device 500, in accordance with various embodiments of the present disclosure. The example method 1200 will now be described with further reference to FIGS. 1-10 for ease of understanding. It is understood that the method 1200 is applicable to structures other than those of FIGS. 1-10. Further, it is understood that additional operations can be provided before, during, and after the method 1200, and some of the operations described below can be replaced or eliminated, in an alternative embodiment of the method 1200.

In operation 1210, the local I/O circuit 530A, 530B reads data stored in the bit cells 210 of the memory arrays 510A-510D. In operation 1220, the tracking circuit activator 450 activates the tracking circuits 400A-400D according to a predefined activation protocol that distributes workload among the tracking circuits 400A-400D. At this time, the tracking circuit 400A-400D activated in operation 1220 mimics the behavior of the bit cell 210. Following this, in operation 1230, the pseudo write driver 410 drives the tracking bit line (TRKBL[0]) associated with the tracking circuit 400A-400D activated in operation 1220. Concurrently, in operation 1240, the clock signal generator 420 asserts an internal clock signal (INT_CLK) on the tracking word line (TRKWL[0]) of the tracking circuit 400A-400D activated in operation 1220.

Subsequently, in operation 1250, the sense amplifier enable signal (SAE) generator 430 generates a sense amplifier enable signal (SAE) based on the combination of the voltage level on the tracking bit line (TRKBL[0]) and the trigger signal (TRIG) generated by the clock signal generator 420. In operation 1260, the sense amplifier 300 amplifies a voltage difference between the bit line pair (BL, BL′), whereby the local I/O circuit determines the bit stored in the bit cell 210 as either high (logic 1) or low (logic 0). Thereafter, in operation 1270, the global I/O circuit outputs the data read by the local I/O circuit 530A, 530B.

In certain embodiments, method 1200 further includes: selectively connecting the pseudo write driver 410 to the tracking bit line (TRKBL[0]); selectively connecting the clock signal generator to the tracking bit line (TRKBL[0]); selectively connecting the clock signal generator 420 to the tracking word line (TRKWL[0]); and pre-charging segments of the tracking bit line (TRKBL[0]) to a predetermined voltage level, e.g., substantially equal to the supply voltage (Vdd), the reference voltage (Vss), or halfway between the supply voltage (Vdd) and the reference voltage (Vss).

In an embodiment, a memory device comprises a memory array, a plurality of sense amplifiers, a plurality of tracking circuits, and a tracking circuit activator. The memory array includes a plurality of bit cells that are arranged in an array of rows and columns and that store data therein, a plurality of word lines each connected to the bit cells in a respective row, and a plurality of bit line pairs each connected to the bit cells in a respective column. Each sense amplifier amplifies a voltage difference between a respective bit line pair in response to a sense amplifier enable signal. The voltage difference represents a bit stored in a bit cell. The tracking circuits are connected to each of the sense amplifiers. Each tracking circuit mimics a behavior of the memory array and generates the sense amplifier enable signal when activated. The tracking circuit activator activates the tracking circuits according to a predefined activation protocol.

In another embodiment, a memory device comprises a plurality of memory arrays, a plurality of sense amplifiers, a plurality of tracking circuits, and a tracking circuit activator. Each memory array includes a plurality of bit cells that are arranged in an array of rows and columns and that store data therein, a plurality of word lines each connected to the bit cells in a respective row, and a plurality of bit line pairs each connected to the bit cells in a respective column. Each sense amplifier amplifies a voltage difference between a respective bit line pair in response to a sense amplifier enable signal. The voltage difference represents a bit stored in a bit cell. The tracking circuits are connected to each of the sense amplifiers. Each tracking circuit mimics a behavior of the memory array and generates the sense amplifier signal when activated. The number of the tracking circuits is less or greater than the number of the memory arrays.

In another embodiment, a method for reducing electromigration in a memory device comprises: reading data stored in a memory array of the memory device; activating tracking circuits of the memory device according to a predefined activation protocol; driving a tracking bit line of the activated tracking circuit; asserting a tracking word line of the activated tracking circuit; generating a sense amplifier enable signal; amplifying a voltage difference between a bit line pair of the memory array; and outputting the data read from the memory array.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device comprising:
a memory array including:
a plurality of bit cells arranged in an array of rows and columns and configured to store data therein;
a plurality of word lines each connected to the bit cells in a respective row; and
a plurality of bit line pairs each connected to the bit cells in a respective column;
a plurality of sense amplifiers each configured to amplify a voltage difference between a respective bit line pair in response to a sense amplifier enable signal, the voltage difference representing a bit stored in a bit cell;
a plurality of tracking circuits connected to each of the sense amplifiers, each tracking circuit configured to mimic a behavior of the memory array and to generate the sense amplifier enable signal when activated; and
a tracking circuit activator configured to activate the tracking circuits according to a predefined activation protocol that distributes workload between the tracking circuits.

2. The memory device of claim 1, wherein the predefined activation protocol includes activating the tracking circuits sequentially, cyclically, randomly, pseudorandomly, alternately, in a clockwise pattern, in a counter-clockwise pattern, in a zigzag pattern, in an interlace manner, or combinations thereof.

3. The memory device of claim 1, further comprising:
the tracking circuit includes:
a tracking bit line;
a tracking word line; and
a plurality of tracking bit cells connected between the tracking bit line and the tracking word line; and
a pseudo write driver configured to receive a write enable signal and an internal clock signal and to drive the tracking bit line.

4. The memory device of claim 3, further comprising a multiplexer connected between the pseudo write driver and the tracking bit line and configured to selectively connect the pseudo write driver to the tracking bit line.

5. The memory device of claim 3, further comprising a clock signal generator configured to generate an inverted version of the internal clock signal.

6. The memory device of claim 5, further comprising a sense amplifier enable signal generator configured to receive a combination of a trigger signal from the clock signal generator and a voltage signal on the tracking bit line and to generate the sense amplifier enable signal.

7. The memory device of claim 3, further comprising a multiplexer connected between the clock signal generator and the tracking bit line and configured to selectively connect the tracking bit line to the clock signal generator.

8. The memory device of claim 1, further comprising a pre-charger connected between segments of the tracking bit line and configured to pre-charge the tracking bit line to a predetermined voltage level.

9. A memory device comprising:
a plurality of memory arrays, each memory array including:
a plurality of bit cells arranged in an array of rows and columns and configured to store data therein;
a plurality of word lines each connected to the bit cells in a respective row; and
a plurality of bit line pairs each connected to the bit cells in a respective column;
a plurality of sense amplifiers each configured to amplify a voltage difference between a respective bit line pair in response to a sense amplifier enable signal, the voltage difference representing a bit stored in a bit cell; and
two or more tracking circuits connected to each of the sense amplifiers, each tracking circuit configured to mimic a behavior of the memory array and to generate the sense amplifier signal when activated, wherein a number of the tracking circuits is less or greater than a number of the memory arrays.

10. The memory device of claim 9, wherein the tracking circuit includes:
a tracking bit line;
a tracking word line; and
a plurality of tracking bit cells connected between the tracking bit line and the tracking word line.

11. The memory device of claim 10, further comprising:
a pseudo write driver configured to receive a write enable signal and an internal clock signal and to drive the tracking bit line; and
a multiplexer connected between the pseudo write driver and the tracking bit line and configured to selectively connect the pseudo write driver to the tracking bit line.

12. The memory device of claim 11, further comprising:
a clock signal generator configured to generate an inverted version of the internal clock signal; and
a sense amplifier enable signal generator configured to receive a combination of a trigger signal from the clock signal generator and a voltage signal on the tracking bit line and to generate a sense amplifier enable signal.

13. The memory device of claim 11, further comprising:
a clock signal generator configured to generate an internal clock signal; and
a multiplexer connected between the clock signal generator and the tracking word line and configured to selectively connect the clock signal generator to the tracking word line.

14. A method for reducing electromigration in a memory device, the method comprising:
reading data stored in a memory array of the memory device;
activating tracking circuits of the memory device according to a predefined activation protocol that distributes workload between the tracking circuits;
driving a tracking bit line of the activated tracking circuit;
asserting a tracking word line of the activated tracking circuit;
generating a sense amplifier enable signal;
amplifying a voltage difference between a bit line pair of the memory array; and
outputting the data read from the memory array.

15. The method of claim 14, wherein driving the tracking bit line is in response to a write enable signal and an internal clock signal.

16. The method of claim 14, wherein generating the sense amplifier enable signal is in response to a voltage signal on the tracking bit line.

17. The method of claim 14, further comprising selectively connecting a clock signal generator to the tracking word line.

18. The method of claim 14, further comprising selectively connecting a clock signal generator to the tracking bit line.

19. The method of claim 14, further comprising selectively connecting a pseudo write driver to the tracking bit line.

20. The method of claim 14, further comprising pre-charging segments of the tracking bit line to a predetermined voltage level.
